(19) United States
(12) Patent Application Publication
(10) Pub. No.: US 2026/0018383 A1
(43) Pub. Date: Jan. 15, 2026

(54) MULTI-PLENUM GAS MANIFOLDS FOR SUBSTRATE PROCESSING SYSTEMS

(71) Applicant: LAM RESEARCH CORPORATION, Fremont, CA (US)

(72) Inventors: Janardhan Achari Murkai SITHARAMACHARI, Bangalore (IN); Sushanth KONDI, Bangalore (IN); Premkumar RAJAGOPAL, Bangalore (IN)

(21) Appl. No.: 18/881,084

(22) PCT Filed: Jun. 22, 2023
(86) PCT No.: PCT/US2023/025915

§ 371 Date: Jan. 3, 2025

Related U.S. Application Data
(60) Provisional application No. 63/359,545, filed on Jul. 8, 2022.

(51) Int. Cl. H01J 37/32

(52) U.S. Cl. CPC H01J 37/3244; H01J 2237/3321; H01J 2237/334; H01J 2237/3365

(57) ABSTRACT

A multi-plenum gas manifold is disclosed and includes a monolithic body, a first plenum and a second plenum. The first plenum is arranged within the monolithic body and configured to distribute to or divert from one or more substrate processing stations a first gas species. The first plenum includes a first cavity and a first set of channels extending outward from the first cavity. The second plenum is arranged within the monolithic body isolated from the first plenum and configured to distribute to or divert from the one or more substrate processing stations a second gas species. The second plenum includes a second cavity disposed radially outward of the first cavity. The second set of channels extends outward from the second cavity.

### CROSS-REFERENCE TO RELATED APPLICATIONS

This application claims the benefit of U.S. Provisional Application No. 63/359,545 filed on Jul. 8, 2022. The entire disclosure of the above application is incorporated herein by reference.

### FIELD

The present disclosure relates to gas divert and distribution systems of substrate processing tools.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to perform etching, deposition, and/or other treatment of substrates such as semiconductor wafers. Example processes that may be performed on a substrate include, but are not limited to, a plasma enhanced chemical vapor deposition (PECVD) process, a physical vapor deposition (PVD) process, an ion implantation process, and/or other etch, deposition, and cleaning processes. As an example, during a deposition process, a substrate may be arranged on an electrostatic chuck (ESC) in a substrate processing system and a thin film may be deposited on the substrate.

### SUMMARY

A multi-plenum gas manifold is disclosed and includes a monolithic body, a first plenum and a second plenum. The first plenum is arranged within the monolithic body and configured to distribute to or divert from one or more substrate processing stations a first gas species. The first plenum includes a first cavity and a first set of channels extending outward from the first cavity. The second plenum is arranged within the monolithic body isolated from the first plenum and configured to distribute to or divert from the one or more substrate processing stations a second gas species. The second plenum includes a second cavity disposed radially outward of the first cavity. The second set of channels extends outward from the second cavity.

In other features, the first cavity and the second cavity are circular shaped. In other features, the first cavity and the second cavity are concentric cavities. In other features, at least one of the first cavity and the second cavity is not circular shaped.

In other features, the multi-plenum gas manifold further includes one or more caps configured to close off the first cavity and the second cavity. In other features, the one or more caps include: a first cap configured to close off the first cavity; and a second cap configured to close off the second cavity. In other features, the first cap is thicker than the second cap. In other features, the first cavity is deeper than the second cavity.

In other features, a volume of the first cavity is equal to a volume of the second cavity. In other features, a volume of the first cavity is different than a volume of the second cavity.

In other features, the first set of channels includes draw channels and a divert channel. The draw channels draw the first gas species into the first cavity. The first cavity directs the first gas species from the draw channels to the divert channel.

In other features, the first set of channels includes a source channel and distribution channels. The distribution channels distribute the first gas species from the first cavity. The first cavity receives the first gas species from the source channel and distributes the first gas species to the distribution channels.

In other features, the second set of channels includes draw channels and a divert channel. The draw channels draw the second gas species into the second cavity. The second cavity directs the second gas species from the draw channels to the divert channel.

In other features, the second set of channels includes a source channel and distribution channels. The distribution channels distribute the second gas species from the second cavity. The second cavity receives the second gas species from the source channel and distributes the second gas species to the distribution channels. In other features, the second set of channels are at least one of axially or vertically offset from the first set of channels.

In other features, the multi-plenum gas manifold further includes a third plenum isolated from the first plenum and the second plenum and including a third cavity and a third set of channels. In other features, the third cavity is radially adjacent to a portion of the first cavity and axially adjacent to a portion of the second cavity. In other features, the third set of channels includes a total of two channels.

In other features, the multi-plenum gas manifold further includes couplers connected to the first set of channels and the second set of channels and configured to connect to conduits to transfer the first gas species and the second gas species between the multi-plenum gas manifold and substrate processing stations.

In other features, a substrate processing system is provided and includes: the multi-plenum gas manifold; and a substrate processing chamber including multiple substrate processing stations. The multi-plenum gas manifold transfers the first gas species and the second gas species between the multi-plenum gas manifold and the substrate processing stations.

In other features, the substrate processing system further includes conduits. The multi-plenum gas manifold includes couplers connected to the first set of channels and the second set of channels. The conduits are connected to the couplers and transfer the first gas species and the second gas species between the multi-plenum gas manifold and the substrate processing stations.

In other features, the first set of channels includes draw channels and a divert channel. The draw channels are connected respectively to the substrate processing stations and draw the first gas species into the first cavity from the substrate processing stations. The first cavity directs the first gas species from the draw channels to the divert channel.

In other features, the first set of channels includes a source channel and distribution channels. The distribution channels are connected respectively to the substrate processing stations and distribute the first gas species from the first cavity to the substrate processing stations. The first cavity receives the first gas species from a gas source and distributes the first gas species to the distribution channels.

In other features, the second set of channels includes draw channels and a divert channel. The draw channels are connected respectively to the substrate processing stations and draw the second gas species into the second cavity from the substrate processing stations. The second cavity directs the second gas species from the draw channels to the divert channel.

In other features, the second set of channels includes a source channel and distribution channels. The distribution channels are connected respectively to the substrate processing stations and distribute the second gas species from the second cavity to the substrate processing stations. The second cavity receives the second gas species from a gas source and distributes the second gas species to the distribution channels.

In other features, a number of channels in the first set of channels is less than or equal to a total number of substrate processing stations in the substrate processing chamber plus one. In other features, a number of channels N in the second set of channels is less than equal to a total number M of substrate processing stations in the substrate processing chamber plus one.

In other features, the first set of channels includes draw channels and a divert channel. A total number of draw channels of the first plenum is less than or equal to a total number of substrate processing stations in the substrate processing chamber.

In other features, the first set of channels includes a source channel and distribution channels. A total number of distribution channels of the first plenum is less than or equal to a total number of substrate processing stations in the substrate processing chamber.

In other features, the second set of channels includes draw channels and a divert channel. A total number of draw channels of the second plenum is less than or equal to a total number of substrate processing stations in the substrate processing chamber.

In other features, the second set of channels includes a source channel and distribution channels. A total number of distribution channels of the second plenum is less than or equal to a total number of substrate processing stations in the substrate processing chamber.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a substrate processing system including one or more multi-plenum gas manifolds implemented to distribute different gas species to multiple processing stations in accordance with an embodiment of the present disclosure;

FIG. 2 is a top view of a substrate processing chamber including a multi-plenum gas manifold implemented to divert different gas species from multiple processing stations in accordance with an embodiment of the present disclosure;

FIG. 3 is a functional block diagram of a gas divert system including a multi-plenum gas manifold in accordance with an embodiment of the present disclosure;

FIG. 4 is a top perspective view of a dual-plenum gas manifold in accordance with the present disclosure;

FIG. 5 is a top view of the dual-plenum gas manifold of FIG. 4;

FIG. 6 is a side cross-sectional view of the dual-plenum gas manifold of FIGS. 4-5 taken at section line A-A of FIG. 5;

FIG. 7 is a side cross-sectional top perspective view of the dual-plenum gas manifold of FIGS. 4-5 taken at section line B-B of FIG. 5;

FIG. 8 is a bottom view of the dual-plenum gas manifold of FIGS. 4-5;

FIG. 9 is a side view of the dual-plenum gas manifold of FIGS. 4-5;

FIG. 10 is cross-sectional top perspective view of a portion of the dual-plenum gas manifold of FIGS. 4-5;

FIG. 11 is a perspective view of a tri-plenum gas manifold in accordance with an embodiment of the present disclosure;

FIG. 12 is a cross-sectional top perspective view illustrating an upper portion of the tri-plenum gas manifold of FIG. 11;

FIG. 13 is a cross-section view of a dual-plenum lower portion of the tri-plenum gas manifold of FIG. 11 in accordance with an embodiment of the present disclosure;

FIG. 14 is a top perspective exploded view of the tri-plenum gas manifold of FIG. 11;

FIG. 15 is a top view of a portion of another tri-plenum gas manifold including concentric cavities in accordance with the present disclosure;

FIG. 16 is a perspective view of the portion of the tri-plenum manifold of FIG. 15; and

FIG. 17 is a cross-sectional top view of a portion of a multi-plenum manifold in accordance with another embodiment of the present disclosure.

In the drawings, reference numbers may be reused to identify similar and/or identical elements.

### DETAILED DESCRIPTION

A multi-station processing tool can include multiple processing stations disposed in a processing chamber. Various gas species may be supplied to and diverted from the substrate processing stations during substrate processing. In order to facilitate distribution and diversion of the gas species one or more stacks of distinct manifolds may be used, where each manifold is used to i) distribute a particular gas species to multiple processing stations, or ii) divert a particular gas species from the multiple processing stations. Each of the manifolds that distributes a gas species, may receive the gas species from a source, such as a gas box, and supply the gas species to multiple stations. Each of the manifolds used to divert a gas species, may receive the gas species from multiple stations and divert the collected gas species to a foreline (or large exhaust line). The more gas species supplied and/or diverted, the more manifolds and corresponding supply and divert lines incorporated in the tool. Each of the manifolds may include a respective housing including top and bottom walls. Depending on the processing system, there can be a large number of manifolds and corresponding supply and divert lines, which requires a significant amount of available space within a tool. Due to a limited amount of available space, this type of arrangement can be crowded and/or not feasible.

The examples set forth herein include multi-plenum gas manifold arrangements configured for compact and centralized gas distribution and diversion. The arrangements minimize a corresponding amount of space occupied within a tool and allow for an increased number of plenums with a minimal increase in amount of space occupied. The arrangements are extendable for any number of plenums. Each of the multi-plenum gas manifolds disclosed herein includes multiple plenums having respectively a cavity and multiple channels extending radially outward from the cavity. The compactness in design of the multi-plenum gas manifolds is due to the arrangement of the cavities and the layered arrangement of inlet and outlet gas channels at multiple axial levels.

The disclosed examples include multi-plenum gas manifolds with concentric and/or radially offset cavities. The cavities have different shapes and/or dimensions. Some examples include monolithic bodies with multiple cavities and respective sets of channels. In some examples, the channels of a first cavity extend adjacent to and/or through one or more other cavities. The channels of the first cavity are axially offset from the channels of the one or more other cavities to ease attachment and access to couplers of the sets of channels. Each of the plenums in a multi-plenum gas manifold may include a N-to-M relationship between a number of inlet channels and a number of outlet channels, where N and M are integers greater than or equal to one. In some examples, longitudinal centers of channels of different plenums within a multi-plenum gas manifold are arranged in a same plane or axially offset to be arranged in different planes. These and other example embodiments are further described below.

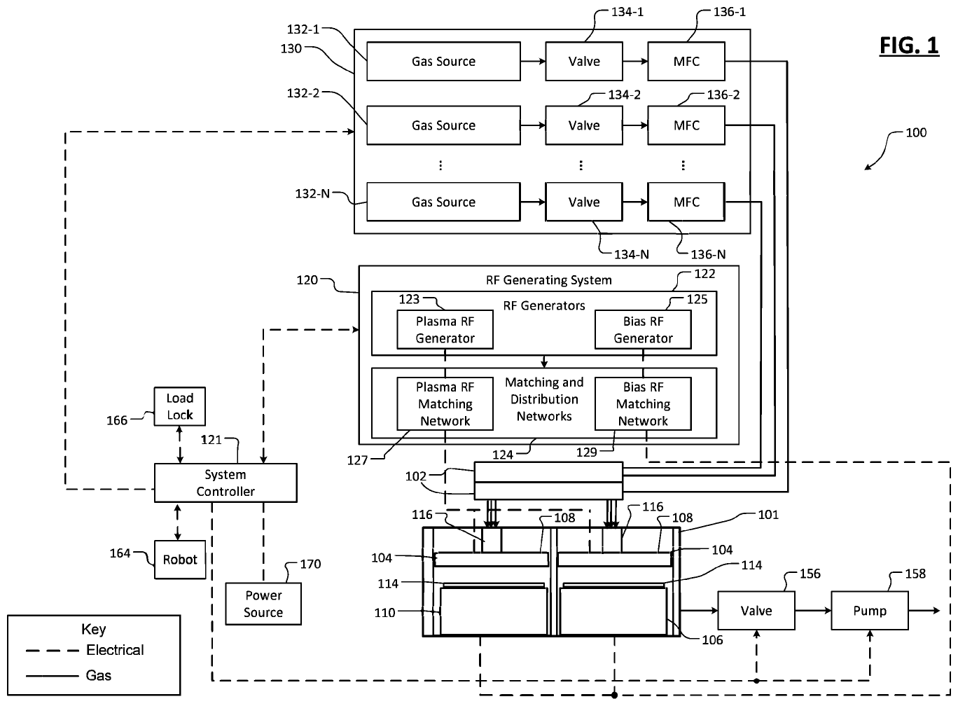

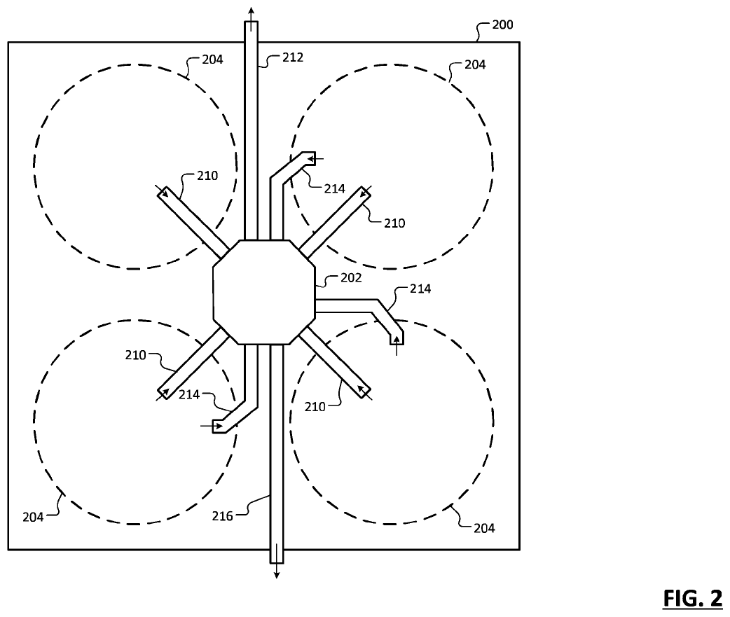

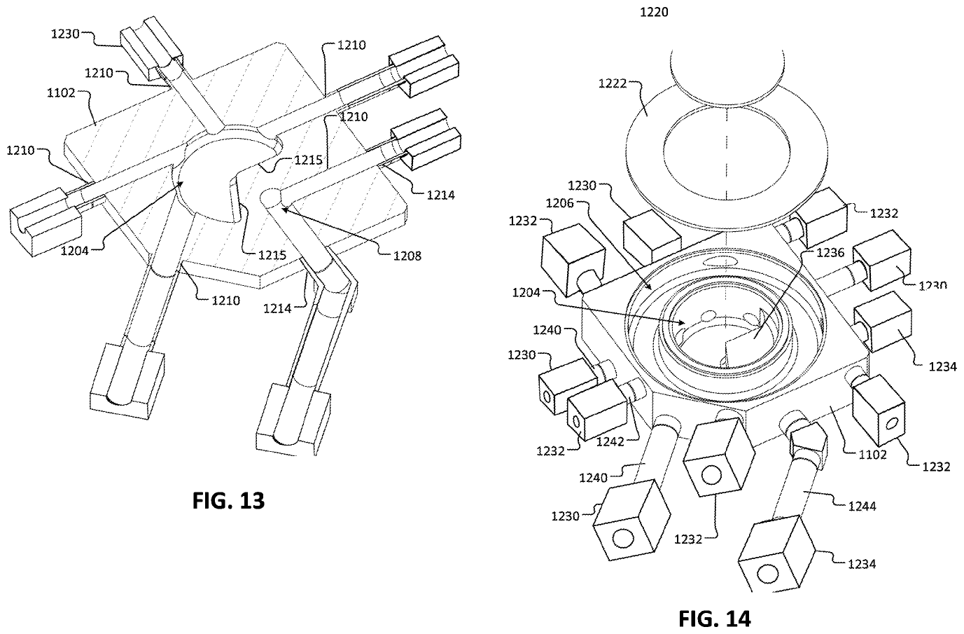

FIG. 1 shows a substrate processing system (or tool) 100 including a processing chamber 101 and one or more multi-plenum gas manifolds 102 implemented to distribute different gas species to multiple processing stations (two processing stations 104 are shown in FIG. 1) within the processing chamber 101. Examples of the multi-plenum gas manifolds 102 are shown and described with respect to FIGS. 2-17. Although FIG. 1 shows distribution manifolds (i.e., the multi-plenum gas manifolds 102), the substrate processing system 100 may include divert manifolds, examples of which are shown in FIGS. 2-17. Each of the multi-plenum gas manifolds shown in FIGS. 2-17 may be implemented as distribution and/or divert manifolds. Each plenum of each of the multi-plenum gas manifolds may be connected up to operate as (i) a distribution plenum including one supply channel and one or more distribution channels, where gas flows through the manifold in a first direction, or (ii) a divert plenum including one or more draw channels and a single divert channel, where gas flows through the manifold in a reverse (or second) direction. Each plenum may be used to supply or divert only a single gas species. In one embodiment, one or more plenums are used to supply a gas mixture including, for example, a processing (or reactive) gas used for an etch, deposition or clean process and an inert gas (e.g., Argon).

Referring to FIG. 1, each of the processing stations includes respective substrate supports (e.g., substrate supports 106), such as electrostatic chucks, and showerheads (e.g., showerheads 108). Each of the processing stations 104 includes upper and lower electrodes. The showerheads may be implemented as or include the upper electrodes. The substrate supports may be implemented as or include the lower electrodes. The upper and lower electrodes may be implemented as radio frequency (RF) electrodes, bias electrodes, clamping electrodes and/or heating electrodes. For example only, the upper electrodes may be implemented as the showerheads, which introduce and distributes gases in the processing stations. The showerheads may include stem portions 116 including ends connected to top surfaces of the processing chamber 101. The showerheads are generally cylindrical and extend radially outward from opposite ends of the stem portions 116 at a location that is spaced from the top surface of the processing chamber. Substrate-facing surfaces of the showerheads include holes through which process or purge gas flows. Alternately, the showerheads may include a conducting plate and the gases may be introduced in another manner.

An RF generating system 120 generates and outputs RF voltages to the upper electrodes and the lower electrodes. For each of the processing stations, one of the upper electrodes and the lower electrodes may be DC grounded, AC grounded or at a floating potential. For example only, the RF generating system 120 may be controlled by a system controller 121 and include one or more RF generators 122 (e.g., a capacitive coupled plasma RF power generator, a bias power generator, and/or other RF power generator) that generate RF voltages, which are fed by one or more matching and distribution networks 124 to the upper electrodes and/or the lower electrodes. The system controller 121 sets and adjusts frequencies of RF signals output from the RF generators 123, 125. The frequencies may be adjusted to adjust power distribution within and across the substrate supports.

As an example, a first RF generator 123, a second RF generator 125, a first RF matching network 127 and a second RF matching network 129 are shown. The first RF generator 123 and the first RF matching network 127 may provide a RF voltage or may simply connect the showerheads to a ground reference. The second RF generator 125 and the second RF matching network 129 may each or collectively be referred to as a power source and provide a RF/bias voltage to the substrate supports. In one embodiment, the first RF generator 123 and the first RF matching network 127 provides power that ionizes gas and drives plasma. In another embodiment, the second RF generator 125 and the second RF matching network 129 provides power that ionizes gas and drives plasma. One of the RF generators 123, 125 may be a high-power RF generator producing, for example 6-10 kilo-watts (KW) of power or more.

A gas delivery system 130 includes one or more gas sources 132-1, 132-2, . . . , and 132-N (collectively gas sources 132), where N is an integer greater than zero. The gas sources 132 supply one or more precursors and gas mixtures thereof. The gas sources 132 may also supply etch gas, carrier gas and/or purge gas. Vaporized precursor may also be used. The gas sources 132 are connected by valves 134-1, 134-2, . . . , and 134-N (collectively valves 134) and mass flow controllers 136-1, 136-2, . . . , and 136-N (collectively mass flow controllers 136) to respective plenums of one or more multi-plenum gas manifolds 102. Outputs of the manifolds 102 are fed to the processing stations of the chamber 101. For example only, the outputs of the manifolds 102 may be fed to the showerheads.

A valve 156 and pump 158 may be used to evacuate reactants from the processing chamber 101. Although a single valve 156 and pump 158 are shown, additional valves and/or pumps may be included. For gas diversion, one or more multi-plenum gas manifolds may be utilized, as further described below.

The system controller 121 may control components of the substrate processing system 100 including controlling supplied RF power levels, pressures and flow rates of supplied gases, RF matching, etc. The system controller 121 controls states of the valve 156 and the pump 158. A robot 164 may be used to deliver substrates into, and remove substrates from the processing stations 104. For example, the robot 164 may transfer substrates between the substrate supports 106 and a load lock 166. The robot 164 may be controlled by the system controller 121. The system controller 121 may control operation of the load lock 166. The valves, gas and/or coolant pumps, power sources, RF generators, etc. may be referred to as actuators.

The substrate processing system 100 further includes a power source 170 that may supply power to the system controller 121. The power source 170 may be controlled by the system controller 121. The system controller 121 may control supply of power from the power source 170 to the RF generating system 120.

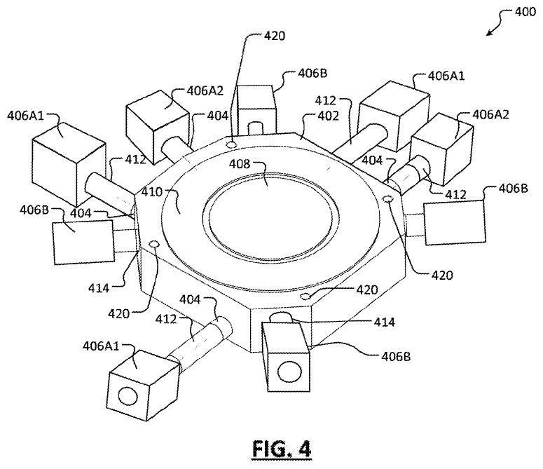

FIG. 2 shows a top view of a substrate processing chamber 200 including a multi-plenum gas manifold 202 implemented to divert different gas species from multiple processing stations 204. In the example of FIG. 2, the multi-plenum gas manifold 202 is shown including two plenums. Each of the plenums has multiple draw input channels and a single divert output channel. The first plenum includes draw input channels 210 and a divert output channel 212. The second plenum includes draw input channels 214 and a divert output channel 216. The draw input channels 210, divert output channel 212, draw input channels 214, divert output channel 216 extend outward from the multi-plenum gas multi-plenum gas manifold 202 to various points in the processing stations 204. Each of the plenums may have one or more draw input channels respectively for one or more of the processing stations 204. In the example shown, the first plenum has four draw input channels and the second plenum has three draw input channels. The channels may include respective couplers. Example couplers are shown in FIG. 4-14. Although the manifold 202 is shown as being octagon shaped, the multi-plenum gas manifold 202 may be shaped differently and have a different number of sides. As an example, the multi-plenum gas manifold 202 may be circular shaped.

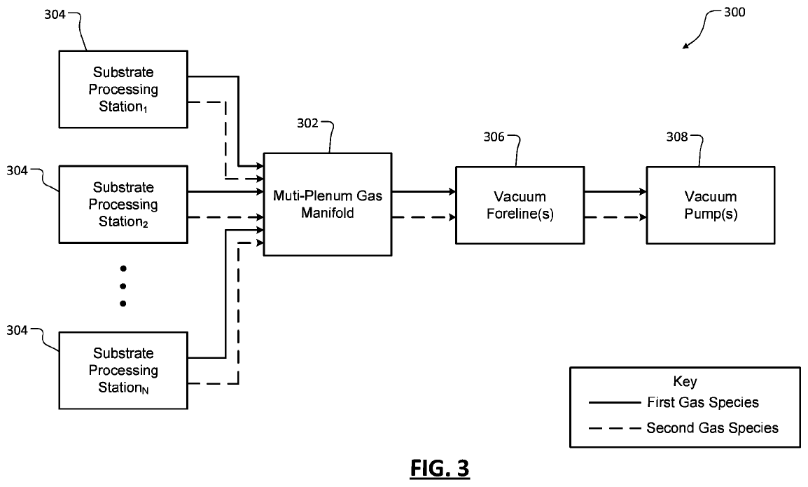

FIG. 3 shows a gas divert system 300 including a multi-plenum gas manifold 302 receiving gas species from multiple substrate processing stations 304. As an example, the multi-plenum gas manifold 302 may include two plenums, where each plenum receives a particular gas species from the substrate processing stations 304. The first plenum may receive a first gas species from each of the substrate processing stations 304. The second plenum may receive a second gas species from each of the substrate processing stations 304. The multi-plenum gas manifold 302 receives the two gas species and directs the gas species to respective vacuum foreline(s) 306. One or more vacuum pumps 308 may draw the gas species from the substrate processing stations 304 to the vacuum foreline(s) 306 via the multi-plenum gas manifold 302. The vacuum pumps 308 may be controlled by a system controller, such as the system controller 121 of FIG. 1.

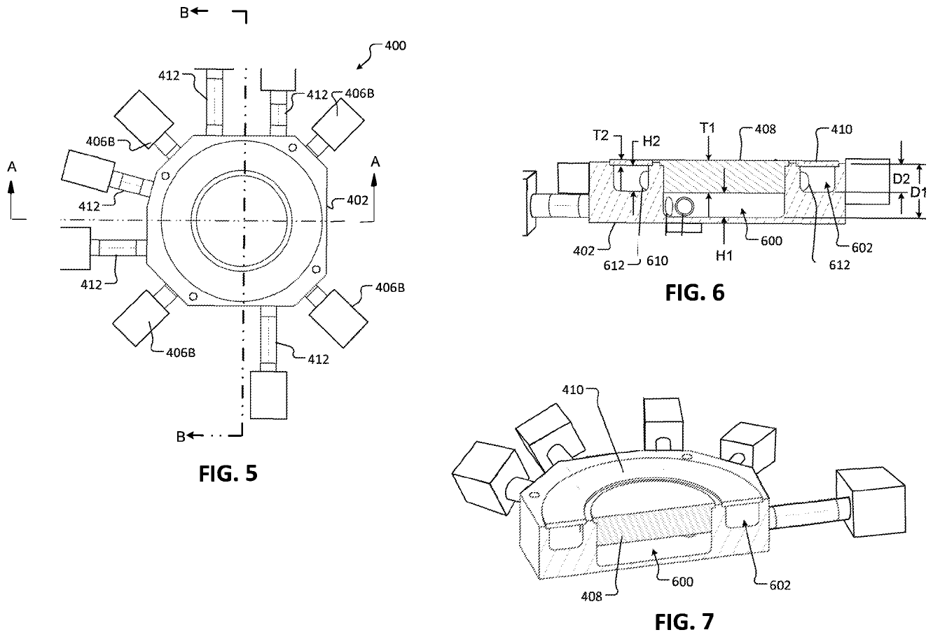

FIGS. 4-5 show a dual-plenum gas manifold 400 (also referred to as a multi-plenum gas manifold) that includes a body 402, channels (outward protruding portions of some of the channels are designated 404), couplers 406, and caps 408, 410. The plenums are isolated from each other. The couplers 406 may be (i) welded directly to the channels having outward protruding portions, or (ii) indirectly connected to the channels 404 via conduits 412, as shown by couplers 406A. The couplers 406A may be welded onto the conduits 412, which are welded onto protrusions of channels of the body 402. The couplers 406A may be female style couplers 406A1 or male type couplers 406A2. The couplers 406 may be screwed into threaded holes 414 in the body 402, as shown by couplers 406B.

The body 402 includes mounting holes 420 through which fasteners may extend to, for example, fasten the body 402 to a top plate of a processing chamber (e.g., the processing chamber 101 of FIG. 1). The fasteners may be bolts that extend through the holes 420 and are threaded into the top plate.

The caps 408, 410 cover and close off respectively a first cavity 600 and a second cavity 602 of two plenums of the dual-plenum gas manifold 400 shown in FIGS. 6-7. The caps 408, 410 may be concentric and the first cavity 600 and second cavity 602 may be concentric, such that the second cavity 602 is disposed radially outward of the first cavity 600. FIG. 6 shows a side cross-sectional view of the dual-plenum gas manifold 400 of FIGS. 4-5 taken at section line A-A of FIG. 5. FIG. 7 shows a side cross-sectional top perspective view of the dual-plenum gas manifold 400 of FIGS. 4-5 taken at section line B-B of FIG. 5. The first plenum of the dual-plenum gas manifold 400 refers to the first cavity 600 and channels extending from the first cavity 600. The second plenum of the dual-plenum gas manifold 400 refers to the second cavity 602 and channels extending from the second cavity 602. The first cavity 600 may be capped by the cap 408, which may be press fit, welded, and/or attached in another manner to the body 402.

The first cavity 600 may have a first depth D1 and the second cavity 602 may have a second depth D2. The first cap 408 has a first thickness T1 and the second cap 410 has a second thickness T2, which may be less than T1. The thickness T1 may be less than the thickness T2 such that a first volume of the first cavity 600 is similar to a second volume of the second cavity 602. The first cavity 600 may have a height H1 and is based on the thickness T1. The second cavity 602 may have a height H2 and is based on the thickness T2. In the example shown, the first cavity 600 is deeper than the second cavity 602. In FIG. 6, a couple of channels 610 of the first plenum are shown and a couple of channels 612 of the second plenum are shown. The first volume of the first cavity 600 may be the same or different than the second volume of the second cavity 602.

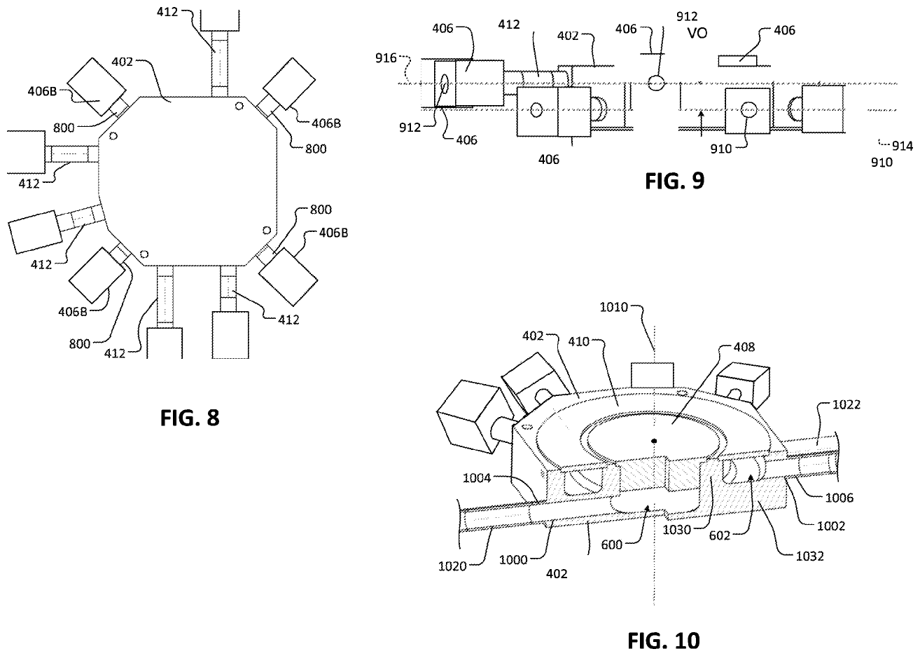

FIG. 8 shows a bottom view of the dual-plenum gas manifold 400 of FIGS. 4-5 including the body 402. Channels of the body 402 are connected to conduits 412 and conduits 800 of the couplers 406B. FIG. 9 shows a side view of the dual-plenum gas manifold 400 of FIGS. 4-5. One of each of the conduits 412, 800 are shown and some of the couplers 406 are shown. The channels of the first plenum are vertically and axially offset from the channels of the second plenum. A vertical offset VO between centers of the channels of the first plenum and centers of channels of the second plenum is shown. The vertical offset VO may be based on the outer diameters of the channels. The greater the outer diameters, the larger the offset. As an example, the outer diameter of the channels may be 0.375 inches (or 9.525 millimeters (mm)) and the vertical offset may be between 0.25-0.5 inches (or 6.35-12.7 mm). In an embodiment, none of the channels of the first and second plenums annularly overlap. In an embodiment, the channels of the first and second plenums do not criss-cross each other.

Longitudinal centerlines of the channels of the plenums may be arranged in a same plane or may be axially offset to be arranged in different planes as shown. In FIG. 9, center points 910 of channels of the first plenum and center points 912 of channels of the second plenum are shown and refer to longitudinal centerlines, which extend along the lengths of the channels. The longitudinal centerlines of the first plenum are in a first plane 914. The longitudinal centerlines of the second plenum are in a second plane 916, which is offset axially and vertically from the first plane 914.

FIG. 10 shows a portion of the dual-plenum gas manifold 400 of FIGS. 4-5 illustrating a cross-section through a portion of the body 402 and a couple of the channels of the dual-plenum gas manifold 400. The channels are designated 1000, 1002 and have corresponding couplers 406A1. The channels 1000, 1002 have protruding portions 1004, 1006 that extend outward from the body 402. To form the body 402, an initial block of material may be cross drilled to provide the channels 1000, 1002 and then an outer portion of the block of material may be machined to remove material and provide the protruding portions 1004, 1006. The channels 1000, 1002 as well as other channels of the body 402 may extend radially outward from a centerline 1010 of the body 402. Conduits 1020, 1022 may be welded to the protruding portions 1004, 1006 and to the couplers 406A1. FIG. 10 also shows a cross-sectional portion 1030 of the body 402 that provides a circular separation wall between the cavities 600, 602 and extends upward from a base portion 1032.

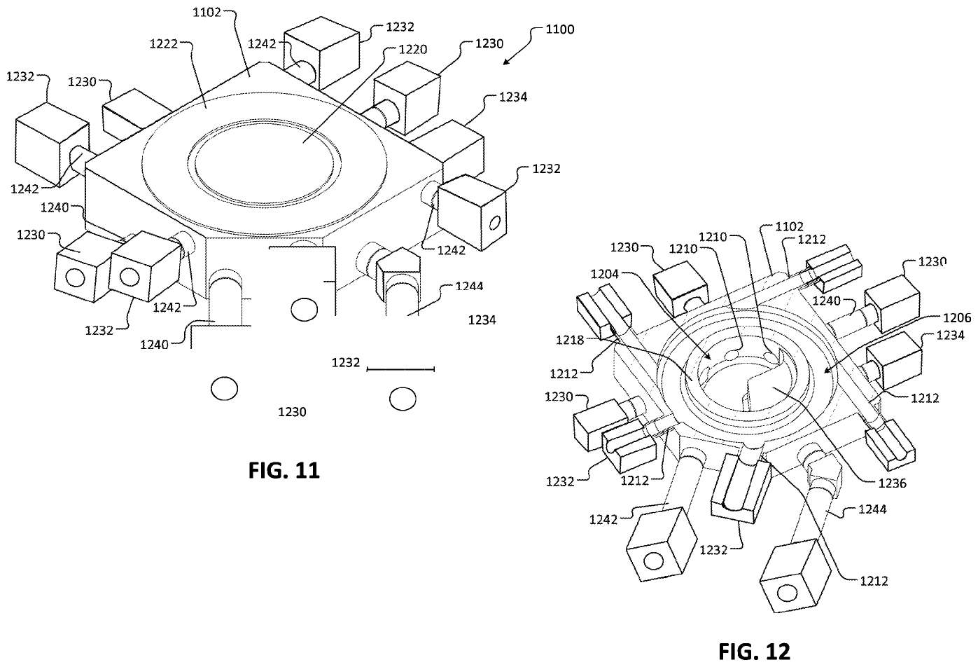

FIGS. 11-14 shows a tri-plenum gas manifold 1100 that includes a body 1102 and three plenums including respectively a first cavity 1204, a second cavity 1206, and a third cavity 1208 and corresponding sets of channels. The first plenum includes the first cavity 1204 and a first set of channels 1210. The second plenum includes the second cavity 1206 and a second set of channels 1212. The third plenum includes the third cavity 1208 and a third set of channels 1214. In the example shown, the third set of channels includes a total of two channels. The first cavity 1204 may be notched to accommodate the third cavity 1208, as shown, such that a portion of the first cavity is crescent shaped with inner edges 1215 nearest the third cavity 1208 being linear. In an embodiment, the channels 1214 extend at a 90° angle relative to each other. A separation wall 1218 exists between the first cavity 1204 and the second cavity 1206.

The body 1102 includes caps 1220, 1222 for covering and closing off the first cavity 1204 the second cavity 1206. The caps 1220, 1222 may be configured similarly as the caps 408, 410 of FIGS. 4-5. The caps 1220, 1222 may be concentric and the first cavity 1204 and the second cavity 1206 may be concentric. The first cavity 1204 is circular shaped and the second cavity 1206 is ring shaped.

The first set of channels 1210 are connected to couplers 1230. The second set of channels 1212 are connected to couplers 1232. The third set of channels 1214 are connected to the couplers 1234. The first set of channels 1210 may be connected to couplers 1230 via conduits, some of which are designated 1240. The second set of channels 1212 may be connected to couplers 1232 via conduits, some of which are designated 1242. The third set of channels 1214 may be connected to couplers 1234 via conduits, one of which are designated 1244. A portion 1236 of the body 1102 partially encasing the third cavity 1208 is shown in FIGS. 12 and 14. The third cavity 1208 is laterally (or radially) adjacent a portion of the first cavity 1204 and axially adjacent to a portion of the second cavity 1206. The portion 1236 protrudes radially inward into a portion of the first cavity 1204.

The first plenum, the second plenum and the third plenum are isolated from each other and may operate as distribution or divert plenums. Each of the plenums when distributing gas species may include a single source channel and one or more distribution channels. Each of the plenums when diverting gas species may include a single divert channel and one or more draw channels. Each plenum may have an equal or fewer number of distribution or draw channels as there are a number of substrate processing stations in a corresponding substrate processing chamber. In an embodiment, none of the channels annularly overlap. In an embodiment, the channels do not criss-cross each other.

Although the multi-plenum gas manifolds of FIGS. 4-14 are shown having two caps, the multi-plenum gas manifolds may have a single cap that closes off multiple cavities or may have no cap. In one embodiment, the bodies of the multi-plenum gas manifolds are formed such that the openings shown in FIGS. 4-14 as being closed off by caps are covered by top walls of the bodies. Each top wall is integrally formed as part of the corresponding body.

The bodies of the multi-plenum gas manifolds of FIGS. 4-14 may be formed of stainless steel, a nickel-based alloy, aluminum and/or other suitable materials. In one embodiment, the bodies are formed of materials that are suitable to withstand passage of corrosive gas species and pressures of the gas species.

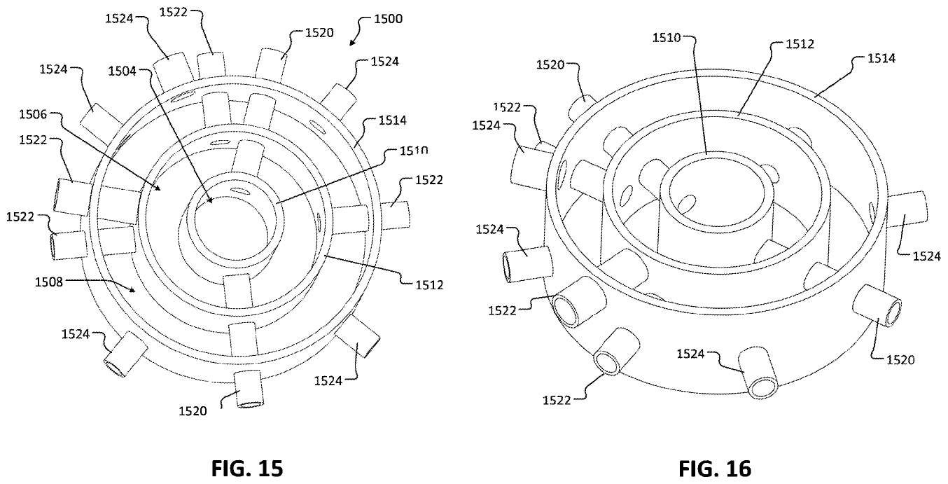

FIGS. 15-16 show a portion 1500 of another tri-plenum gas manifold including concentric cavities. The portion 1500 is provided to illustrate that a multi-plenum gas manifold may include three or more concentric cavities and corresponding sets of channels. The multi-plenum gas manifolds of FIGS. 1-14 may be configured to include any number of concentric cavities and corresponding sets of channels.

The tri-plenum gas manifold includes a body having a first cavity 1504, a second cavity 1506, and a third cavity 1508. The body may include a first circular wall 1510 enclosing at least a portion of the first cavity 1504, a second circular wall 1512 enclosing at least a portion of the second cavity 1506 and a third circular wall 1514 enclosing at least a portion of the third cavity 1508. The body may have a bottom circular wall that closes off bottoms of the first cavity 1504, the second cavity 1506, and the third cavity 1508. The body may also include caps that respectively close off tops of the cavities 1504, 1506, 1508, similar to the caps shown and described for the multi-plenum gas manifolds of FIGS. 4-14. In an embodiment, the body is a monolithic body.

The first cavity 1504 has channels 1520 extending radially outward therefrom. The second cavity 1506 has channels 1522 extending radially outward therefrom. The third cavity 1508 has channels 1524 extending radially outward therefrom. The channels 1520, 1522, 1524 may be axially, vertically and/or annularly offset from each other. Two or more of the channels 1520, 1522, 1524 may be axially offset from each other and annularly overlap each other. For example, a first channel may be axially offset from a second channel and annularly overlap the second channel such that the first channel is at least partially above the second channel. In an embodiment, none of the channels 1520, 1522, 1524 annularly overlap. In an embodiment, the channels 1520, 1522, 1524 do not criss-cross each other. The channels 1520, 1522, 1524 may be linear channels as shown or may be non-linear.

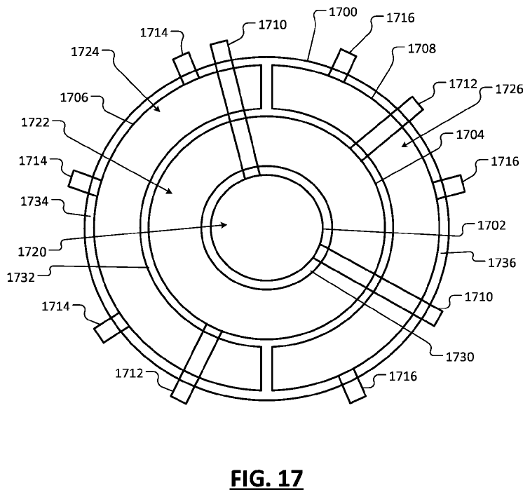

FIG. 17 shows a portion 1700 of a multi-plenum gas manifold, which is similar to the tri-plenum gas manifold of FIG. 15-16. The multi-plenum gas manifold includes multiple plenums 1702, 1704, 1706, 1708. The plenums 1702, 1704 are concentric. The plenums 1706, 1708 may be semi-circular arch shaped. The plenums 1706, 1708 do not have circular cavities. The plenums 1702, 1704, 1706, 1708 have respective cavities and sets of channels. Each of the plenums 1702, 1704, 1706, 1708 may have any number of channels. In the example shown, the plenum 1702 has two channels 1710, the plenum 1704 has two channels 1712, the plenum 1706 has three channels 1714, the plenum 1708 has three channels 1716. Although the multi-plenum gas manifold is shown having a particular number of circular cavities (e.g., the first cavity 1720 and the second cavity 1722 of plenums 1702 1704) and non-circular cavities (e.g., the third cavity 1724 and fourth cavity 1726 of plenums 1706, 1708), the multi-plenum gas manifold may include any number of circular cavities and any number of noncircular cavities. As an example, the plenum 1704 may be divided to provide two non-circular cavities, similarly shaped as the cavities of the plenums 1706, 1708.

The multi-plenum gas manifold may include a body. The body may include a first circular wall 1730 enclosing at least a portion of the first cavity 1720, a second circular wall 1732 enclosing at least a portion of the second cavity 1722, a side wall 1734 enclosing at least a portion of the third cavity 1724, and a side wall 1736 enclosing at least a portion of the fourth cavity 1726. The body may have a bottom circular wall that closes off bottoms of the first cavity 1720, the second cavity 1722, the third cavity 1724, and the fourth cavity 1726. The body may also include caps that respectively close off tops of the first cavity 1720, the second cavity 1722, the third cavity 1724, and the fourth cavity 1726, similar to the caps shown and described for the multi-plenum gas manifolds of FIGS. 4-14. In an embodiment, the body is a monolithic body.

The examples disclosed herein include multi-plenum gas manifolds with multi-level gas flow paths that ensure gas species stay isolated as the gas species are distributed to and/or diverted from substrate processing stations.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from multiple fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A multi-plenum gas manifold comprising:
a monolithic body;
a first plenum arranged within the monolithic body and configured to distribute to or divert from one or more substrate processing stations a first gas species, the first plenum comprising
a first cavity, and
a first set of channels extending outward from the first cavity; and
a second plenum arranged within the monolithic body isolated from the first plenum and configured to distribute to or divert from the one or more substrate processing stations a second gas species, the second plenum comprising
a second cavity disposed radially outward of the first cavity, and
a second set of channels extending outward from the second cavity.

2. The multi-plenum gas manifold of claim 1, wherein the first cavity and the second cavity are circular shaped.

3. The multi-plenum gas manifold of claim 1, wherein the first cavity and the second cavity are concentric cavities.

4. The multi-plenum gas manifold of claim 1, wherein at least one of the first cavity and the second cavity is not circular shaped.

5. The multi-plenum gas manifold of claim 1, further comprising one or more caps configured to close off the first cavity and the second cavity.

6. The multi-plenum gas manifold of claim 5, wherein the one or more caps comprise:
a first cap configured to close off the first cavity; and
a second cap configured to close off the second cavity.

7. The multi-plenum gas manifold of claim 6, wherein the first cap is thicker than the second cap.

8. The multi-plenum gas manifold of claim 7, wherein the first cavity is deeper than the second cavity.

9. The multi-plenum gas manifold of claim 1, wherein a first volume of the first cavity is equal to a second volume of the second cavity.

10. The multi-plenum gas manifold of claim 1, wherein a first volume of the first cavity is different than a second volume of the second cavity.

11. The multi-plenum gas manifold of claim 1, wherein:
the first set of channels comprises a plurality of draw channels and a divert channel;
the plurality of draw channels draw the first gas species into the first cavity; and
the first cavity directs the first gas species from the plurality of draw channels to the divert channel.

12. The multi-plenum gas manifold of claim 1, wherein:
the first set of channels comprises a source channel and a plurality of distribution channels;
the plurality of distribution channels distribute the first gas species from the first cavity; and
the first cavity receives the first gas species from the source channel and distributes the first gas species to the plurality of distribution channels.

13. The multi-plenum gas manifold of claim 1, wherein:
the second set of channels comprises a plurality of draw channels and a divert channel;
the plurality of draw channels draw the second gas species into the second cavity; and
the second cavity directs the second gas species from the plurality of draw channels to the divert channel.

14. The multi-plenum gas manifold of claim 1, wherein:
the second set of channels comprises a source channel and a plurality of distribution channels;
the plurality of distribution channels distribute the second gas species from the second cavity; and
the second cavity receives the second gas species from the source channel and distributes the second gas species to the plurality of distribution channels.

15. The multi-plenum gas manifold of claim 1, wherein the second set of channels are at least one of axially or vertically offset from the first set of channels.

16. The multi-plenum gas manifold of claim 1, further comprising a third plenum isolated from the first plenum and the second plenum and comprising a third cavity and a third set of channels.

17. The multi-plenum gas manifold of claim 16, wherein the third cavity is radially adjacent to the first cavity and axially adjacent to the second cavity.

18. The multi-plenum gas manifold of claim 16, wherein the third set of channels includes a total of two channels.

19. The multi-plenum gas manifold of claim 1, further comprising a plurality of couplers connected to the first set of channels and the second set of channels and configured to connect to a plurality of conduits to transfer the first gas species and the second gas species between the multi-plenum gas manifold and a plurality of substrate processing stations.

20. A substrate processing system comprising:
the multi-plenum gas manifold of claim 1; and
a substrate processing chamber comprising a plurality of substrate processing stations,
wherein the multi-plenum gas manifold transfers the first gas species and the second gas species between the multi-plenum gas manifold and the plurality of substrate processing stations.

21. The substrate processing system of claim 20, further comprising a plurality of conduits, wherein:
the multi-plenum gas manifold comprises a plurality of couplers connected to the first set of channels and the second set of channels; and
the plurality of conduits connected to the plurality of couplers and transferring the first gas species and the second gas species between the multi-plenum gas manifold and the plurality of substrate processing stations.

22. The substrate processing system of claim 20, wherein:
the first set of channels comprises a plurality of draw channels and a divert channel;
the plurality of draw channels are connected respectively to the plurality of substrate processing stations and draw the first gas species into the first cavity from the plurality of substrate processing stations; and
the first cavity directs the first gas species from the plurality of draw channels to the divert channel.

23. The substrate processing system of claim 20, wherein:
the first set of channels comprises a source channel and a plurality of distribution channels;
the plurality of distribution channels are connected respectively to the plurality of substrate processing stations and distribute the first gas species from the first cavity to the plurality of substrate processing stations; and
the first cavity receives the first gas species from a gas source and distributes the first gas species to the plurality of distribution channels.

24. The substrate processing system of claim 20, wherein:
the second set of channels comprises a plurality of draw channels and a divert channel;
the plurality of draw channels are connected respectively to the plurality of substrate processing stations and draw the second gas species into the second cavity from the plurality of substrate processing stations; and
the second cavity directs the second gas species from the plurality of draw channels to the divert channel.

25. The substrate processing system of claim 20, wherein:
the second set of channels comprises a source channel and a plurality of distribution channels;
the plurality of distribution channels are connected respectively to the plurality of substrate processing stations and distribute the second gas species from the second cavity to the plurality of substrate processing stations; and
the second cavity receives the second gas species from a gas source and distributes the second gas species to the plurality of distribution channels.

26. The substrate processing system of claim 20, wherein a number of channels in the first set of channels is less than or equal to a total number of substrate processing stations in the substrate processing chamber plus one.

27. The substrate processing system of claim 20, wherein a number of channels N in the second set of channels is less than equal to a total number M of substrate processing stations in the substrate processing chamber plus one.

28. The substrate processing system of claim 20, wherein:
the first set of channels comprises a plurality of draw channels and a divert channel; and
a total number of draw channels of the first plenum is less than or equal to a total number of substrate processing stations in the substrate processing chamber.

29. The substrate processing system of claim 20, wherein:
the first set of channels comprises a source channel and a plurality of distribution channels; and
a total number of distribution channels of the first plenum is less than or equal to a total number of substrate processing stations in the substrate processing chamber.

30. The substrate processing system of claim 20, wherein:
the second set of channels comprises a plurality of draw channels and a divert channel; and
a total number of draw channels of the second plenum is less than or equal to a total number of substrate processing stations in the substrate processing chamber.

31. The substrate processing system of claim 20, wherein:
the second set of channels comprises a source channel and a plurality of distribution channels; and
a total number of distribution channels of the second plenum is less than or equal to a total number of substrate processing stations in the substrate processing chamber.
